(19) United States
(12) Patent Application Publication
(10) Pub. No.: US 2026/0314408 A1
(43) Pub. Date: Oct. 8, 2026

(54) HETEROJUNCTION BIPOLAR TRANSISTOR

(71) Applicant: GlobalFoundries U.S. Inc., Malta, NY (US)

(72) Inventors: Oscar Dario Restrepo, Halfmoon, NY (US); Anupam Dutta, Kokata (IN); Vibhor Jain, Clifton Park, NY (US); Alexander Montgomery Derrickson, Saratoga Springs, NY (US); Vvss Satyasuresh Choppalli, Bangalore (IN)

(21) Appl. No.: 19/173,332

(22) Filed: Apr. 8, 2025

(51) Int. Cl. H01L 23/373; H10D 10/01; H10D 10/80; H10D 80/30

(52) U.S. Cl. CPC H10W 40/254; H10D 10/021; H10D 10/821; H10D 80/30

(57) ABSTRACT

The present disclosure relates to semiconductor structures and, more particularly, to heterojunction bipolar transistors and methods of manufacture. The structure includes: a semiconductor substrate including a bottom semiconductor material and a top semiconductor material; a sub-collector region including the top semiconductor material and an upper semiconductor material over the top semiconductor material; an electrically insulating heat dissipative material at junction between the top semiconductor material and the upper semiconductor material of the sub-collector region; a collector region above the sub-collector region; an intrinsic base over the collector region; an extrinsic base over the intrinsic base; and an emitter region adjacent to the extrinsic base.

### BACKGROUND

The present disclosure relates to semiconductor structures and, more particularly, to heterojunction bipolar transistors and methods of manufacture.

A heterojunction bipolar transistor (HBT) is a type of bipolar junction transistor (BJT) that uses different semiconductor materials for the emitter and base regions, creating a heterojunction. The HBT can handle signals of very high frequencies, up to several hundred GHz. The HBT can be used, for example, in radio frequency (RF) systems, and in applications requiring a high power efficiency, such as RF power amplifiers in cellular phones and in automotive RADAR applications requiring higher frequency (~140 GHz) operations.

### SUMMARY

In an aspect of the disclosure, a structure comprises: a semiconductor substrate comprising a bottom semiconductor material and a top semiconductor material; a sub-collector region comprising the top semiconductor material and an upper semiconductor material over the top semiconductor material; an electrically insulating heat dissipative material at junction between the top semiconductor material and the upper semiconductor material of the sub-collector region; a collector region above the sub-collector region; an intrinsic base over the collector region; an extrinsic base over the intrinsic base; and an emitter region adjacent to the extrinsic base.

In an aspect of the disclosure, a structure comprises: a semiconductor substrate; a sub-collector region over the semiconductor substrate; electrically insulating heat dissipative material under the sub-collector region and extending into the semiconductor substrate; a collector region over the sub-collector region; an intrinsic base over the collector region; an extrinsic base over the intrinsic base; and an emitter region adjacent to the extrinsic base.

In an aspect of the disclosure, a method comprises: forming a sub-collector region comprising a top semiconductor material of a semiconductor substrate and an upper semiconductor material over the top semiconductor material; forming an electrically insulating heat dissipative material at junction between the top semiconductor material and the upper semiconductor material of the sub-collector region; forming a collector region above the sub-collector region; forming an intrinsic base over the collector region; forming an extrinsic base over the intrinsic base; and forming an emitter region adjacent to the extrinsic base.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a structure and respective fabrication processes in accordance with aspects of the present disclosure.

FIGS. 2 and 3 show additional structures in accordance with aspects of the present disclosure.

FIG. 4 shows a hybrid structure and respective fabrication processes in accordance with aspects of the present disclosure.

FIGS. 5A-5C show respective fabrication processes for fabricating the structure shown in FIG. 1 in accordance with aspects of the present disclosure.

### DETAILED DESCRIPTION

The present disclosure relates to semiconductor structures and, more particularly, to heterojunction bipolar transistors and methods of manufacture. More specifically, the present disclosure relates to heterojunction bipolar transistors (HBT) integrated with an electrically insulating heat dissipative material, e.g., diamond or other carbon-based insulator material. Advantageously, the structures described herein improve self-heating and high frequency performance (e.g., fT and Fmax) of the HBT, in addition to being able to absorb (e.g., mitigate) heat and/or replace an external heat sink. The HBTs described herein also exhibit lower parasitic capacitance.

In more specific embodiments, the electrically insulating heat dissipative material, e.g., diamond or other carbon-based insulator material, may be in contact with or adjacent to a sub-collector region of an HBT. In embodiments, the heat dissipative material, e.g., diamond or other carbon-based insulator material, may be partially overlapping and below the sub-collector region, extending into an underlying semiconductor substrate material. The sub-collector region above the electrically insulating heat dissipative material may comprise polycrystalline and single crystal semiconductor material. The collector may be provided on the single crystal semiconductor material and a collector contact may be provided on the polycrystalline semiconductor material above the electrically insulating heat dissipative material. In any of the embodiments, the electrically insulating heat dissipative material may dissipate heat generated at the collector-base junction (which would otherwise dissipate into the underlying semiconductor substrate). Implementations of the HBTs described herein may be used in, for example, automotive RADAR applications which require higher temperature and higher frequency (~140GHz) operation.

The structures of the present disclosure can be manufactured in a number of ways using a number of different tools. In general, though, the methodologies and tools are used to form structures with dimensions in the micrometer and nanometer scale. The methodologies, i.e., technologies, employed to manufacture the structures of the present disclosure have been adopted from integrated circuit (IC) technology. For example, the structures are built on wafers and are realized in films of material patterned by photolithographic processes on the top of a wafer. In particular, the fabrication of the structures uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

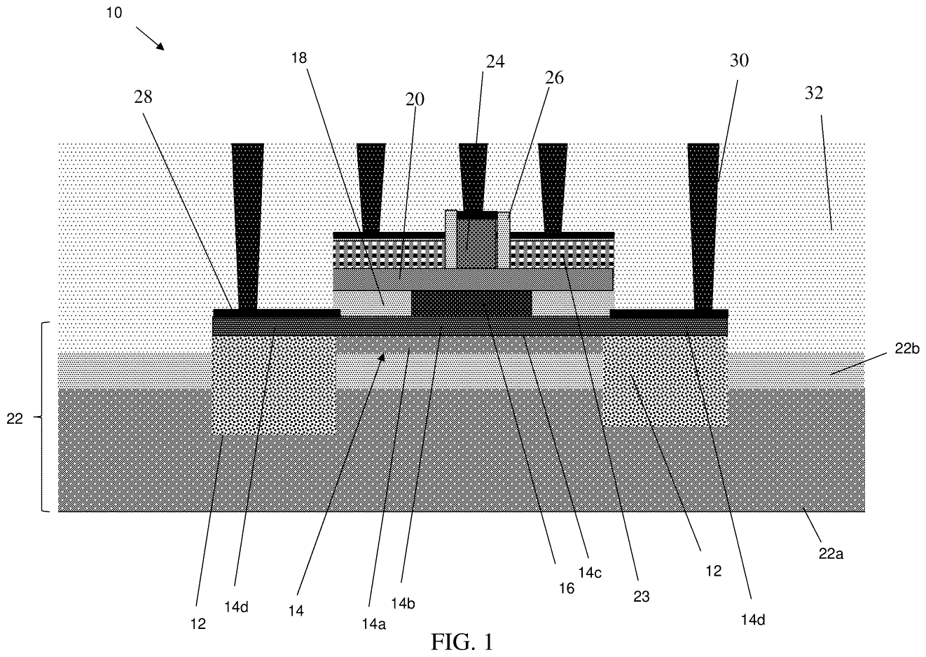

FIG. 1 shows a structure in accordance with aspects of the present disclosure. In embodiments, the structure 10 of FIG. 1 comprises an HBT which includes an electrically insulating heat dissipative material 12 underneath a portion of the sub-collector region 14. In embodiments, the electrically insulating heat dissipative material 12 may partially overlap and be below the sub-collector region 14. For example, the electrically insulating heat dissipative material 12 may be below an upper portion 14b of the sub-collector region 14 and adjacent to a lower portion 14a of the sub-collector region 14. In embodiments, the upper portion 14b of the sub-collector region 14 has a larger dimension (e.g., width) than the lower portion 14a of the sub-collector region 14.

In embodiments, the electrically insulating heat dissipative material 12 may preferably be diamond material; although other materials as described herein are contemplated. For example, the electrically insulating heat dissipative material 12 may be carbon-based materials, or other insulator and heat dissipating material with a dielectric constant of about 5.5 or greater and a thermal conductivity greater than oxide, for example, of about 2200 W/m·K or greater. The electrically insulating heat dissipative material 12 may be used as a heatsink to absorb (e.g., mitigate) heat that is generated at a junction between a collector region 16 and the intrinsic base region 20. This heat dissipation, in turn, will increase device performance.

In more specific embodiments, the structure 10 includes a semiconductor substrate 22. The semiconductor substrate 22 may be semiconductor-on-insulator (SOI) technologies or a bulk substrate as known in the art. In the SOI technology, the semiconductor substrate 22 comprises a top semiconductor material, e.g., the lower portion 14a of the sub-collector region 14, a handle wafer 22a and an insulator material 22b between the handle wafer 22a and the top semiconductor material, e.g., the lower portion 14a of the sub-collector region 14.

In embodiments, the semiconductor material of both the handle wafer 22a and the top semiconductor material may be any semiconductor material, e.g., Si, SiGe, SiGeC, SiC, GaAs, InAs, InP, and other III/V or II/VI compound semiconductors with a suitable single crystallographic orientation (e.g., a (100), (110), (111), or (001) crystallographic orientation). In further embodiments, the semiconductor material of the top semiconductor material may be p-doped semiconductor material for an NPN device or n-doped for an PNP device. The insulator material 22b may comprise any suitable material, including silicon oxide, sapphire, other suitable insulating materials, and/or combinations thereof. An exemplary insulator layer may be a buried oxide layer (BOX).

FIG. 1 further shows the sub-collector region 14 over the insulator material 22b. The sub-collector region 14 includes the lower portion 14a and the upper portion 14b. The upper portion 14b may comprise a middle portion of single crystalline semiconductor 14c material between outer portions of polycrystalline semiconductor material 14d. In this configuration, the polycrystalline semiconductor material 14d is over the electrically insulating heat dissipative material 12 and the single crystalline semiconductor material 14c is over the single crystalline semiconductor material of the lower portion 14a. In embodiments, the upper portion 14b of the sub-collector region 14 may be epitaxially grown semiconductor material on the lower portion 14a of the sub-collector region 14.

The electrically insulating heat dissipative material 12 is adjacent to the lower portion 14a of the sub-collector region 14 and below the upper portion 14b of the sub-collector region 14. Also, the electrically insulating heat dissipative material 12 may extend into the insulator material 22b and the handle wafer 22a. In embodiments, the electrically insulating heat dissipative material 12 is preferably diamond, although other materials are contemplated as described herein.

The collector region 16 may be provided on the sub-collector region 14 and, more specifically, upper portion 14b of the sub-collector region 14. The collector region 16 may comprise semiconductor material that can be either n-doped or p-doped material. For example, an n-type dopant can be used for an NPN device, whereas a p-type dopant can be used for a PNP device. The p-type dopants may be, e.g., Boron (B), and the n-type dopants may be, e.g., Arsenic (As), Phosphorus (P) and Antimony (Sb), among other suitable examples. An insulator material 18 may surround the collector region 16, over the sub-collector region 14. The insulator material 18 may be an oxide material, for example. The collector region 16 may have a smaller profile, e.g., width, than the sub-collector region 14.

An intrinsic base 20 may be provided over the collector region 16 and the insulator material 18. The intrinsic base 20 may be epitaxially grown over the collector region 16 and the insulator material 18. The intrinsic base 20 may be SiGe material epitaxially grown with an in-situ doping. For example, the intrinsic base 20 may include p-type dopant (e.g., boron) for an NPN device or an n-type dopant (e.g., arsenic) for a PNP device.

FIG. 1 further shows the extrinsic base 23 and the emitter region 24. The extrinsic base 23 and the emitter region 24 may be formed over the intrinsic base 20 using epitaxial growth processes as described herein. In embodiments, the extrinsic base 23 may be polycrystalline semiconductor material, e.g., Si. The extrinsic base 23 may be epitaxially grown on the intrinsic base 20 with an in-situ dopant. For example, the extrinsic base 23 may include a p-type dopant (e.g., boron) for an NPN device or an n-type dopant (e.g., arsenic) for a PNP device. The electrically insulating heat dissipative material 12, e.g., diamond, may extend laterally to the sidewalls of the extrinsic base 23 and the intrinsic base 20, in addition to underneath the sub-collector region 14. The extrinsic base 23 may be separated and electrically isolated from the emitter region 24 by insulator material 26, e.g., sidewall spacers. In embodiments, the insulator material 26 may be an oxide or nitride material.

Silicide contacts 28 may be formed on the active regions of the device, e.g., the emitter region 24, the extrinsic base 23 and the sub-collector region 14. As should be understood by those of skill in the art, the silicide process begins with deposition of a thin transition metal layer, e.g., nickel, cobalt or titanium, over fully formed and patterned semiconductor devices. After deposition of the material, the structure is heated allowing the transition metal to react with exposed silicon (or other semiconductor material as described herein) in the active regions of the semiconductor device, forming a low-resistance transition metal silicide. Following the reaction, any remaining transition metal is removed by chemical etching, leaving silicide contacts 28 in the active regions of the device.

FIG. 1 further shows contacts 30 formed to the silicide contacts 28 on the emitter region 24, the extrinsic base 23 and the sub-collector region 14, e.g., polysilicon material 14d of the sub-collector region 14. In this way, the contacts 30 electrically connect to the emitter region 24, the extrinsic base 23and the sub-collector region 14. The contacts 30 may be formed within trenches in interlevel dielectric material 32. The interlevel dielectric material 32 may be layers of oxide and nitride, deposited by conventional deposition methods, e.g., chemical vapor deposition (CVD) process. The contacts 30, e.g., wiring structures and/or via interconnect structures, can be formed by conventional lithography, etching and deposition methods known to those of skill in the art.

By way of example of conventional lithography, etching and deposition methods, a resist is formed over the interlevel dielectric material 32 which is exposed to energy (light) and developed utilizing a conventional resist developer to form a pattern (opening). An etching process with a selective chemistry, e.g., reactive ion etching (RIE), will be used to transfer the pattern from the patterned photoresist layer to form one or more trenches in the interlevel dielectric material 32. Following the resist removal by a conventional oxygen ashing process or other known stripants, conductive material, e.g., aluminum, copper, tungsten, etc., can be deposited by any conventional deposition processes, e.g., CVD processes. Any residual material on the surface of the interlevel dielectric material 32 can be removed by conventional chemical mechanical polishing (CMP) processes.

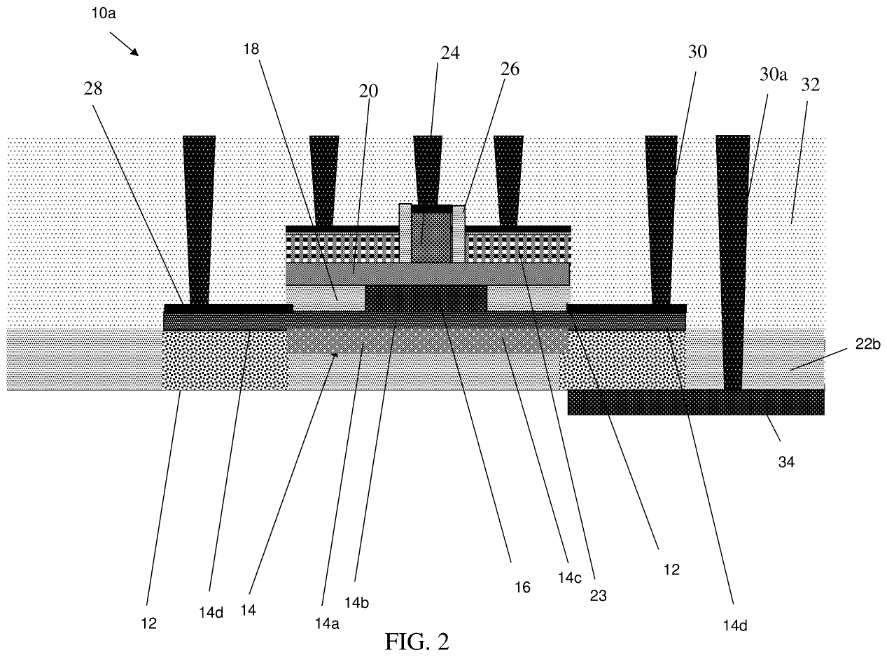

FIG. 2 shows a structure in accordance with additional aspects of the present disclosure. In the structure 10a of FIG. 2, a heat dissipating material 34 is formed on an underside of the insulator material 22b and in contact with the electrically insulating heat dissipative material 14. In embodiments, the heat dissipating material 34 may contact one or both of the electrically insulating heat dissipative material 14. In this configuration, the heat dissipating material 34 will act as an additional heat sink.

A via interconnect structure 30a comprising conductor material contacts an upper side of the heat dissipating material 34, extending through both the interlevel dielectric material 32 and the insulator material 22b. In this embodiment, the handle wafer 22a may be removed to expose the underside of the electrically insulating heat dissipative material 14. This may be performed by conventional planarization processes such as a chemical mechanical process known to those of skill in the art. The heat dissipating material 34 may be a conductive material used in wiring structures, e.g., aluminum, tungsten, etc. The remaining features of the structure 10a are similar to the structure 10 of FIG. 1 such that no further explanation is required for a complete understanding of the present disclosure.

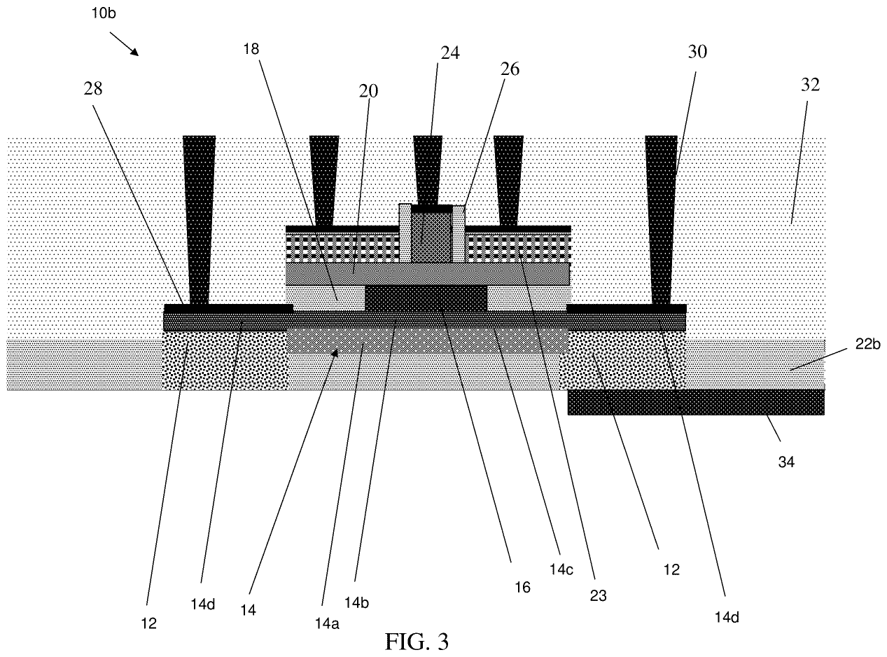

FIG. 3 shows another structure in accordance with additional aspects of the present disclosure. In the structure 10b of FIG. 3, the heat dissipating material 34 is formed on an underside of the insulator material 22b and in contact with the electrically insulating heat dissipative material 12. In this embodiment, the via interconnect structure 30a shown in FIG. 2 may be eliminated. The remaining features of the structure 10b are similar to the structure 10a of FIG. 2 such that no further explanation is required for a complete understanding of the present disclosure.

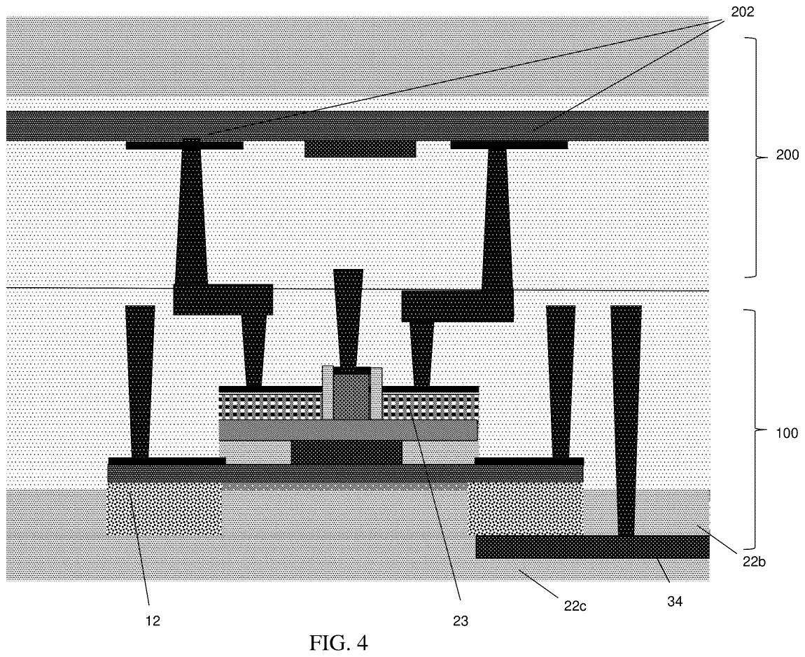

FIG. 4 shows a hybrid structure and respective fabrication processes in accordance with aspects of the present disclosure. The hybrid structure includes an HBT 100 and a conventional CMOS structure 200 bonded together. In the HBT may be any of the structures 10, 10a, 10b shown in FIGS. 1-3, including the electrically insulating heat dissipative material 12 underneath the sub-collector region 14. In this configuration, the heat dissipating material 34 is formed on an underside of the insulator material 22b and covered with additional insulator material 22c (that is of the same material as the insulator material 22b). The base region 23 may be electrically connected to diffusion regions 202 of the CMOS structure 200. The structures 100, 200 may be bonded together by conventional bonding processes such as oxide-oxide bonding as is known in the art.

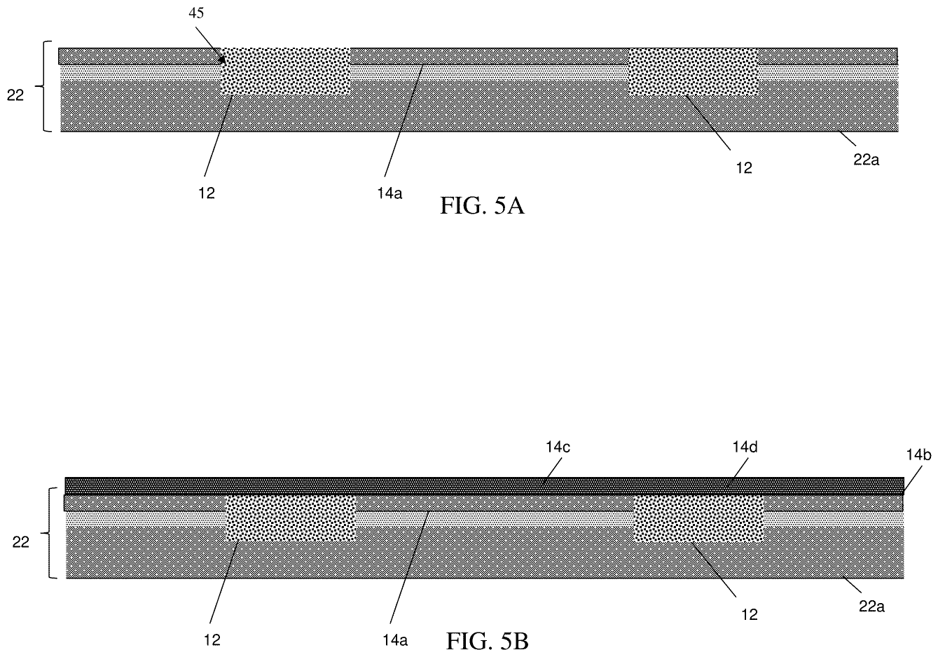

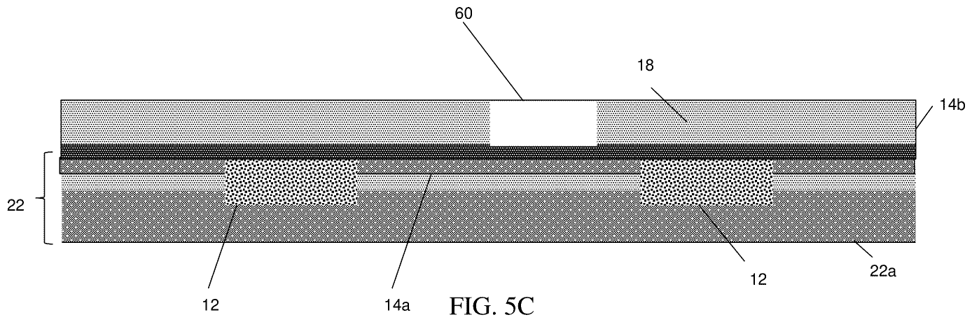

FIGS. 5A-5C show respective fabrication processes for fabricating the structure shown in FIG. 1 in accordance with aspects of the present disclosure. It should be understood that the respective fabrication processes show relevant steps of the formation of the electrically insulating heat dissipative material 12 and part of the HBT, itself. Also, it should be understood by those of skill in the art that the processes shown in FIGS. 5A-5C may also be used for the fabrication of the structures shown in FIGS. 2-4.

By way of example, in FIG. 5A, a trench 45 may be formed in the semiconductor substrate 22, i.e., the top semiconductor material, e.g., the lower portion 14a of the sub-collector region, the handle wafer 22a and the insulator material 22b between the handle wafer 22a and the top semiconductor material, e.g., the lower portion 14a of the sub-collector region. The trench 45 may be formed by conventional lithography and etching processes as described herein. The trench 45 may be filled with the electrically insulating heat dissipative material 12. In embodiments, the electrically insulating heat dissipative material 12 may be deposited by conventional deposition methods, e.g., CVD, followed by a planarization process, e.g., chemical mechanical polishing.

In FIG. 5B, the upper portion 14b of the sub-collector region may be formed over the electrically insulating heat dissipative material 12 and the top semiconductor material, e.g., the lower portion 14a of the sub-collector region. The upper portion 14b may be epitaxially grown Si material, which forms polysilicon material 14d over the electrically insulating heat dissipative material 12 and single crystalline semiconductor material 14c over the area of the upper portion 14b of the sub-collector region between the polysilicon material 14d.

In FIG. 5C, an insulator material 18 is formed over the upper portion 14b of the sub-collector region. In embodiments, the insulator material 18 may be formed by conventional deposition processes, e.g., CVD. A trench 60 is formed in the insulator material 18, between the electrically insulating heat dissipative material 12. In embodiments, the collector material will be formed in the trench 60 by an epitaxial growth process. As further shown in FIG. 1, for example, the remaining portions of the HBT, e.g., collector material 16, intrinsic base 20, extrinsic base 23, emitter 24 (with accompanying sidewall spacers 26) and contacts 30 may be formed by conventional deposition and patterning processes as is known in the art such that no further explanation is required herein for a complete understanding of the present disclosure.

The structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a semiconductor substrate comprising a bottom semiconductor material and a top semiconductor material;
a sub-collector region comprising the top semiconductor material and an upper semiconductor material over the top semiconductor material;
an electrically insulating heat dissipative material at junction between the top semiconductor material and the upper semiconductor material of the sub-collector region;
a collector region above the sub-collector region;
an intrinsic base over the collector region;
an extrinsic base over the intrinsic base; and
an emitter region adjacent to the extrinsic base.

2. The structure of claim 1, wherein the electrically insulating heat dissipative material comprises carbon-based material.

3. The structure of claim 1, wherein the electrically insulating heat dissipative material comprises diamond.

4. The structure of claim 1, wherein the semiconductor substrate further comprises an insulator material between the bottom semiconductor material and the top semiconductor material, and the electrically insulating heat dissipative material extends through the insulator material and into the bottom semiconductor material.

5. The structure of claim 1, wherein the electrically insulating heat dissipative material is on a side of the top semiconductor material and below upper semiconductor material.

6. The structure of claim 1, wherein the upper semiconductor material comprises single crystalline semiconductor material between polycrystalline semiconductor material.

7. The structure of claim 6, wherein the polycrystalline semiconductor material is over the electrically insulating heat dissipative material and the single crystalline semiconductor material is over the top semiconductor material and between the polysilicon material.

8. The structure of claim 7, further comprising sub-collector contacts over the polycrystalline semiconductor material and over the electrically insulating heat dissipative material.

9. The structure of claim 5, further comprising heat dissipative material under the electrically insulating heat dissipative material and contacting to an underside of the insulator material.

10. The structure of claim 9, further comprising a via interconnect structure extending through the insulator material and the bottom semiconductor material, and connecting to the heat dissipative material.

11. The structure of claim 1, further comprising contacts electrically connecting to the collector region, the extrinsic base and the emitter region.

12. A structure comprising:
a semiconductor substrate;
a sub-collector region over the semiconductor substrate;
electrically insulating heat dissipative material under the sub-collector region and extending into the semiconductor substrate;
a collector region over the sub-collector region;
an intrinsic base over the collector region;
an extrinsic base over the intrinsic base; and
an emitter region adjacent to the extrinsic base.

13. The structure of claim 12, wherein the electrically insulating heat dissipative material comprises diamond and is under the extrinsic base and the intrinsic base.

14. The structure of claim 12, wherein the electrically insulating heat dissipative material is at a junction of the sub-collector region.

15. The structure of claim 14, wherein the sub-collector region comprises a top semiconductor material of the semiconductor substrate and another semiconductor material over the top semiconductor material.

16. The structure of claim 15, wherein the electrically insulating heat dissipative material is on a side of the top semiconductor material and below the upper semiconductor material.

17. The structure of claim 16, wherein the upper semiconductor material comprises single crystalline semiconductor material between polycrystalline material.

18. The structure of claim 17, wherein the polycrystalline material contacts the electrically insulating heat dissipative material.

19. The structure of claim 17, further comprising contacts electrically connecting to the sub-collector region and positioned over the polycrystalline material.

20. A method comprising:
forming a sub-collector region comprising a top semiconductor material of a semiconductor substrate and an upper semiconductor material over the top semiconductor material;
forming an electrically insulating heat dissipative material at junction between the top semiconductor material and the upper semiconductor material of the sub-collector region;
forming a collector region above the sub-collector region;
forming an intrinsic base over the collector region;
forming an extrinsic base over the intrinsic base; and
forming an emitter region adjacent to the extrinsic base.
